(19) United States
(12) Patent Application Publication
(10) Pub. No.: US 2014/0042460 A1
(43) Pub. Date: Feb. 13, 2014

(54) SILICON CARBIDE SEMICONDUCTOR DEVICE

(71) Applicant: Sumitomo Electric Industries, Ltd., Osaka-shi (JP)

(72) Inventors: Takeyoshi Masuda, Osaka-shi (JP); Keiji Wada, Osaka-shi (JP); Toru Hiyoshi, Osaka-shi (JP)

(21) Appl. No.: 13/933,872

(22) Filed: Jul. 2, 2013

Related U.S. Application Data
(60) Provisional application No. 61/682,490, filed on Aug. 13, 2012.

(30) Foreign Application Priority Data
Aug. 13, 2012 (JP) 2012-179207

(51) Int. Cl. H01L 29/16; H01L 29/78

(52) U.S. Cl. CPC H01L 29/1608; H01L 29/78
USPC 257/77

(57) ABSTRACT

A silicon carbide substrate has a first surface and a second surface, and includes a first region and a third region each having first conductivity type, as well as a second region and a fourth region each having second conductivity type. The third region surrounds the second region on the second surface. The fourth region has an impurity concentration higher than that of the second region, is in contact with the second region, and surrounds the third region on the second surface. A first main electrode is provided on the first surface. A second main electrode is in contact with each of the third and fourth regions. A gate insulating film is provided on the second region.

### BACKGROUND OF THE INVENTION

1. Field of the Invention

The present invention relates to a silicon carbide semiconductor device, in particular, a silicon carbide semiconductor device having a gate insulating film.

2. Description of the Background Art

Japanese Patent Laying-Open No. 2012-38771 discloses a vertical type MOSFET (Metal Oxide Semiconductor Field Effect Transistor) having a trench. This MOSFET has a p type body layer having a portion serving as a channel region in which an inversion layer is formed. On the p type body layer, an n type source contact layer is formed. A p type contact region is formed to be surrounded by the n type source contact layer. Further, a source electrode is provided in contact with the n type source contact layer and the p type contact region.

When switching the MOSFET from ON state to OFF state, the inversion layer formed in the channel region of the p type body region ceases to exist. Specifically, electrons in the channel region are removed to the source electrode via the contact region. If the migration of the electrons in the channel region to the contact region is insufficient upon switching to OFF state, the MOSFET, which is of enhancement type in the first place, may operate in a manner of depletion type, for example. More generally, insufficient removal of carriers in the channel region upon switching to OFF state may result in fluctuations such that the threshold value for switching comes closer to zero as compared with an intended value, in an extreme case, such that the sign thereof is inversed.

### SUMMARY OF THE INVENTION

The present invention is made to solve such a problem and has an object to provide a silicon carbide semiconductor device allowing for suppression of fluctuations in threshold value for switching.

A silicon carbide semiconductor device of the present invention includes a silicon carbide substrate, a first main electrode, a second main electrode, a gate insulating film, and a gate electrode. The silicon carbide substrate has a first surface and a second surface. The silicon carbide substrate includes: a first region that has first conductivity type; a second region that has second conductivity type different from the first conductivity type; a third region that has the first conductivity type; and a fourth region that has the second conductivity type. The second region is in contact with the first region, is separated from the first surface by the first region, partially constitutes the second surface, and surrounds the first region on the second surface. The third region is in contact with the second region, partially constitutes the second surface, and surrounds the second region on the second surface. The fourth region has an impurity concentration higher than that of the second region, is in contact with the second region, partially constitutes the second surface, and surrounds the third region on the second surface. The first main electrode is provided on the first surface. The second main electrode is in contact with each of the third region and the fourth region. The gate insulating film is provided on the second region. The gate electrode is provided on the gate insulating film.

According to the silicon carbide semiconductor device, the fourth region is provided to surround the second region, which has a portion serving as a channel region. Accordingly, when switching the silicon carbide semiconductor device to OFF state, carriers in the channel region can be removed in all the directions. This suppresses the carriers from remaining in the channel region during OFF state. Accordingly, fluctuations in threshold value for switching can be suppressed.

Preferably, a distance is approximately 3.5 μm or less from a portion, which is composed of the second region, of the second surface to the fourth region via an interface between the second region and the third region. This reduces the distance in which the carriers are migrated to be removed from the channel region to the fourth region when switching to OFF state. Accordingly, when switching to OFF state, the carriers in the channel region can be sufficiently removed more securely.

Preferably, the second region has an impurity concentration of 5×10¹⁷/cm³ or more. This reduces electric resistance in a path, which is disposed in the second region and in which the carriers are migrated to be removed from the channel region to the fourth region when switching to OFF state. Accordingly, when switching to OFF state, the carriers in the channel region can be sufficiently removed more securely.

Preferably, the second region is an epitaxial layer provided on the first region. Accordingly, crystal defect in the second region can be suppressed as compared with a case where the second region is a layer formed by ion implantation. This reduces electric resistance in a path, which is disposed in the second region and in which the carriers are migrated to be removed from the channel region to the fourth region when switching to OFF state. Accordingly, when switching to OFF state, the carriers in the channel region can be sufficiently removed more securely.

Preferably, the second region between the first region and the third region has a thickness of not less than 0.2 μm and not more than 1.5 μm. This reduces electric resistance in a path, which is disposed in the second region between the first region and the third region and in which the carriers are migrated to be removed from the channel region to the fourth region when switching to OFF state. Accordingly, when switching to OFF state, the carriers in the channel region can be sufficiently removed more securely.

In the silicon carbide semiconductor device, a trench having a side wall may be provided in the second surface of the silicon carbide substrate. The second region may be covered with the gate insulating film on the side wall. Accordingly, a trench type silicon carbide semiconductor device is obtained.

In the silicon carbide semiconductor device, the second surface of the silicon carbide substrate may be flat. Accordingly, a planar type silicon carbide semiconductor device is obtained.

As described above, according to the present invention, fluctuations in threshold value for switching of the silicon carbide semiconductor device can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial cross sectional view schematically showing a configuration of a silicon carbide semiconductor device in a first embodiment of the present invention.

FIG. 2 is a partial top view schematically showing a silicon carbide substrate included in the silicon carbide semiconductor device of FIG. 1.

FIG. 3 is a schematic partial cross sectional view taken along a line in FIG. 1.

FIG. 4 is a schematic partial cross sectional view taken along a line IV-IV in FIG. 1.

FIG. 5 is a partial cross sectional view schematically showing a configuration of the silicon carbide substrate included in the silicon carbide semiconductor device of FIG. 1.

FIG. 6 is a partial cross sectional view schematically showing a first step of a method for manufacturing the silicon carbide semiconductor device of FIG. 1.

FIG. 7 is a partial cross sectional view schematically showing a second step of the method for manufacturing the silicon carbide semiconductor device of FIG. 1.

FIG. 8 is a partial cross sectional view schematically showing a third step of the method for manufacturing the silicon carbide semiconductor device of FIG. 1.

FIG. 9 is a partial cross sectional view schematically showing a fourth step of the method for manufacturing the silicon carbide semiconductor device of FIG. 1.

FIG. 10 is a partial cross sectional view schematically showing a fifth step of the method for manufacturing the silicon carbide semiconductor device of FIG. 1.

FIG. 11 is a partial cross sectional view schematically showing how carriers in a channel region are removed when switching the silicon carbide semiconductor device of FIG. 1 to OFF state.

FIG. 12 is a partial cross sectional view schematically showing a configuration of a silicon carbide semiconductor device in a second embodiment of the present invention.

FIG. 13 is a partial top view schematically showing a silicon carbide substrate included in the silicon carbide semiconductor device of FIG. 12.

FIG. 14 is a schematic partial cross sectional view taken along a line XIV-XIV in FIG. 12.

FIG. 15 is a schematic partial cross sectional view taken along a line XV-XV in FIG. 12.

FIG. 16 is a partial cross sectional view schematically showing a configuration of the silicon carbide substrate included in the silicon carbide semiconductor device of FIG. 12.

FIG. 17 is a partial cross sectional view schematically showing a first step of a method for manufacturing the silicon carbide semiconductor device of FIG. 12.

FIG. 18 is a partial cross sectional view schematically showing a second step of the method for manufacturing the silicon carbide semiconductor device of FIG. 12.

FIG. 19 is a partial cross sectional view schematically showing a third step of the method for manufacturing the silicon carbide semiconductor device of FIG. 12.

FIG. 20 is a partial cross sectional view schematically showing a fourth step of the method for manufacturing the silicon carbide semiconductor device of FIG. 12.

FIG. 21 is a partial cross sectional view schematically showing a fifth step of the method for manufacturing the silicon carbide semiconductor device of FIG. 12.

FIG. 22 is a partial cross sectional view schematically showing a sixth step of the method for manufacturing the silicon carbide semiconductor device of FIG. 12.

FIG. 23 is a partial cross sectional view schematically showing a seventh step of the method for manufacturing the silicon carbide semiconductor device of FIG. 12.

FIG. 24 is a partial cross sectional view schematically showing an eighth step of the method for manufacturing the silicon carbide semiconductor device of FIG. 12.

FIG. 25 is a partial cross sectional view schematically showing a ninth step of the method for manufacturing the silicon carbide semiconductor device of FIG. 12.

FIG. 26 is a partial cross sectional view schematically showing a tenth step of the method for manufacturing the silicon carbide semiconductor device of FIG. 12.

FIG. 27 is a partial cross sectional view schematically showing an eleventh step of the method for manufacturing the silicon carbide semiconductor device of FIG. 12.

FIG. 28 is a partial cross sectional view schematically showing a twelfth step of the method for manufacturing the silicon carbide semiconductor device of FIG. 12.

FIG. 29 is a partial cross sectional view schematically showing how carriers in a channel region are removed when switching the silicon carbide semiconductor device of FIG. 12 to OFF state.

FIG. 30 is a graph showing an exemplary relation between a distance L2 in FIG. 16 and a threshold voltage.

FIG. 31 is a partial cross sectional view schematically showing a fine structure of a special plane in the silicon carbide semiconductor substrate.

FIG. 32 shows a crystal structure of a (000-1) plane in a hexagonal crystal of polytype 4H.

FIG. 33 shows a crystal structure in a (11-20) plane along a line XXXIII-XXXIII of FIG. 32.

FIG. 34 shows a crystal structure in the vicinity of a surface of a combined plane of FIG. 31 within a (11-20) plane.

FIG. 35 shows the combined plane of FIG. 31 when viewed from a (01-10) plane.

FIG. 36 shows a variation of FIG. 31.

FIG. 37 is a graph showing an exemplary relation between a channel mobility and an angle between a (000-1) plane and a channel surface macroscopically viewed, in each of a case where thermal etching is performed and a case where no thermal etching is performed.

FIG. 38 is a graph showing an exemplary relation between the channel mobility and an angle between the channel direction and a <0-11-2> direction.

### DESCRIPTION OF THE PREFERRED EMBODIMENTS

The following describes embodiments of the present invention based on figures. It should be noted that in the below-mentioned figures, the same or corresponding portions are given the same reference characters and are not described repeatedly.

Regarding crystallographic indications in the present specification, an individual orientation is represented by [ ], a group orientation is represented by < >, and an individual plane is represented by ( ), and a group plane is represented by { }. In addition, a negative crystallographic index is normally expressed by putting “-” (bar) above a numeral, but is indicated by putting the negative sign before the numeral in the present specification.

### First Embodiment

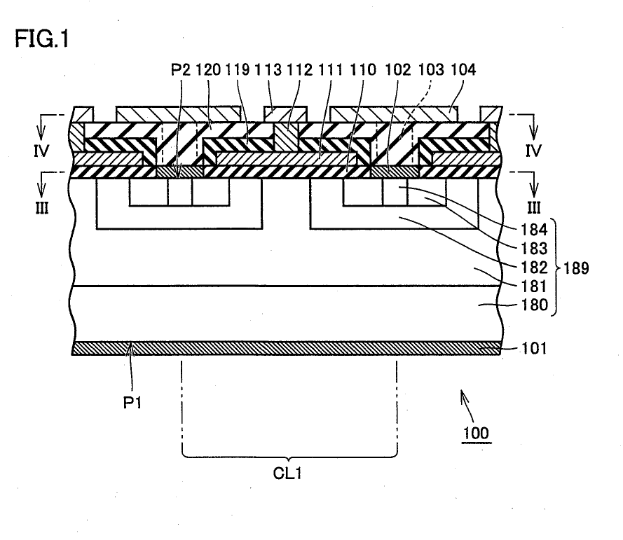

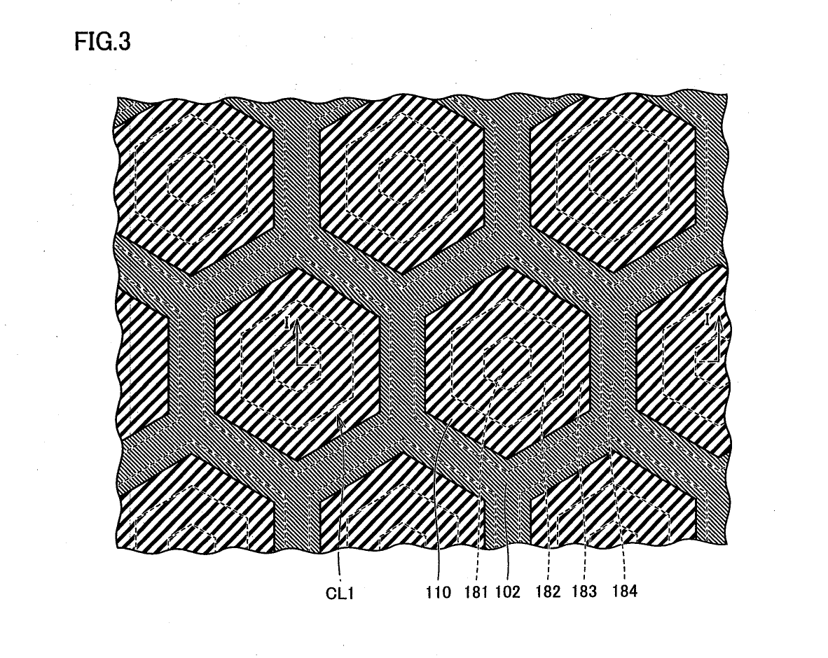

As shown in FIG. 1 to FIG. 4, a MOSFET 100 (silicon carbide semiconductor device) of the present embodiment is a planar type power semiconductor device, and has a plurality of cell structures CL1 periodically arranged. Specifically, MOSFET 100 includes an epitaxial substrate 189, a drain electrode 101 (first main electrode), source electrodes 102 (second main electrodes), source contacts 103, source wires 104, gate oxide films 110 (gate insulating films), gate electrodes 111, gate contacts 112, gate wires 113, and interlayer insulating films 119 and 120.

Epitaxial substrate 189 is made of silicon carbide. The silicon carbide preferably has a crystal structure of hexagonal system, more preferably, of polytype 4H. Epitaxial substrate 189 has a lower surface P1 (first surface) and an upper surface P2 (second surface). Upper surface P2 is flat. In other words, MOSFET 100 is of planar type. Epitaxial substrate 189 includes: a single-crystal substrate 180; a drift region 181 (first region) having n type conductivity (first conductivity type); body regions 182 (second regions) having p type conductivity (second conductivity type different from the first conductivity type); source regions 183 (third regions) having n type conductivity; and contact regions 184 (fourth regions) having p type conductivity.

One surface of single-crystal substrate 180 constitutes lower surface P1. Drift region 181 is provided on an opposite surface of single-crystal substrate 180 to this one surface.

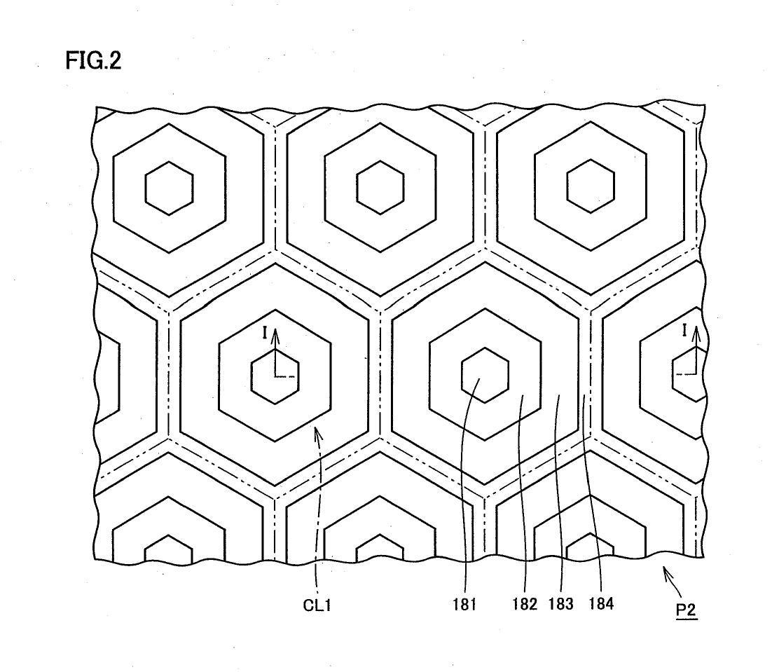

Each of body regions 182 is in contact with drift region 181. Body region 182 is separated from lower surface P1 by drift region 181 (FIG. 1). Body region 182 partially constitutes upper surface P2. On upper surface P2, body region 182 surrounds drift region 181 (FIG. 2). Body region 182 preferably has an impurity concentration of not less than approximately 5×10¹⁷/cm³ and not more than approximately 3×10¹⁸/cm³, for example, has an impurity concentration of approximately 1×10¹⁸/cm³.

Each of source regions 183 is in contact with body region 182. Source region 183 partially constitutes upper surface P2. On upper surface P2, source region 183 surrounds body region 182 (FIG. 2).

Each of contact regions 184 is in contact with body region 182. Contact region 184 partially constitutes upper surface P2. On upper surface P2, contact region 184 surrounds source region 183 (FIG. 2). In the present embodiment, contact region 184 extends on upper surface P2 in the form of a web so as to form a honeycomb shape. Contact region 184 has an impurity concentration higher than that of body region 182.

Drain electrode 101 is provided on lower surface P1. Source electrode 102 is in contact with each of source region 183 and contact region 184. Gate oxide film 110 is provided on body region 182. Gate electrode 111 is provided on gate oxide film 110.

Gate oxide film 110 covers body region 182 on upper surface P2. Gate electrode 111 is provided on gate oxide film 110. An interlayer insulating film 119 covers gate electrode 111. Each of gate oxide film 110 and interlayer insulating film 119 has an opening in which each of source region 183 and contact region 184 is exposed on upper surface P2. In this opening, source electrode 102 is in ohmic contact with each of source region 183 and contact region 184.

Gate contact 112 is provided in a contact hole, which is formed in each of interlayer insulating films 119 and 120, so as to connect gate wire 113 and gate electrode 111 to each other. Source wire 104 is provided on interlayer insulating film 120. Source contact 103 is provided in a contact hole, which is formed in interlayer insulating film 120, so as to connect source wire 104 and source electrode 102 to each other. Gate wire 113 is provided on interlayer insulating film 120. As shown in FIG. 4, gate wire 113 and source wire 104 are arranged alternately, and extend in the same direction.

Drain electrode 101 (FIG. 1) is provided on lower surface P1 of epitaxial substrate 189. Drain electrode 101 is in ohmic contact with lower surface P1 of the epitaxial substrate.

As shown in FIG. 5, a distance L1 is preferably approximately 3.5 μm or less from a portion, which is composed of body region 182, of upper surface P2 to contact region 184 via an interface between body region 182 and source region 183. Further, body region 182 between drift region 181 and source region 183 preferably has a thickness t1 (size in the longitudinal direction in the figure) of approximately 0.2 μm or more, more preferably, approximately 0.3 μm or more. Further, thickness t1 is preferably approximately 1.5 μm or less.

The following describes a method for manufacturing MOSFET 100.

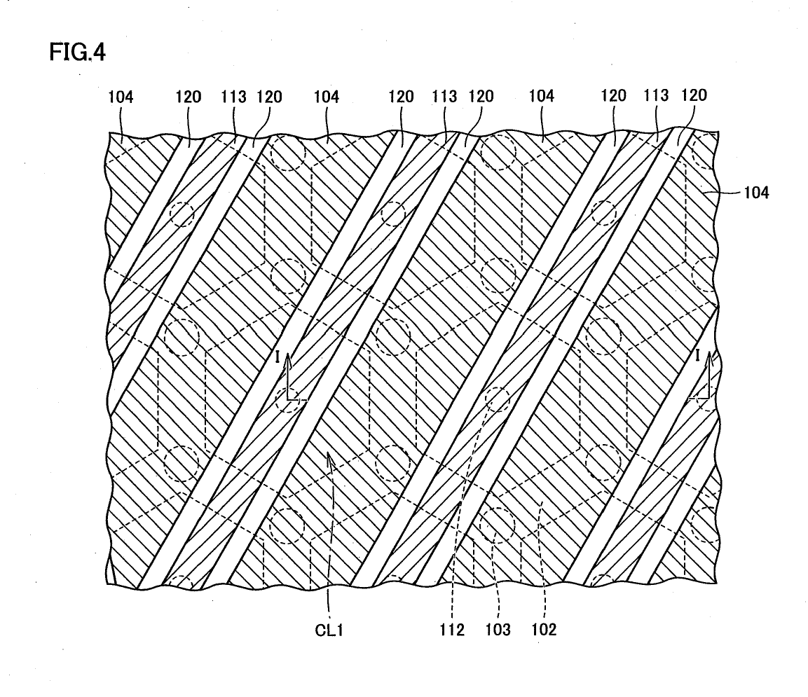

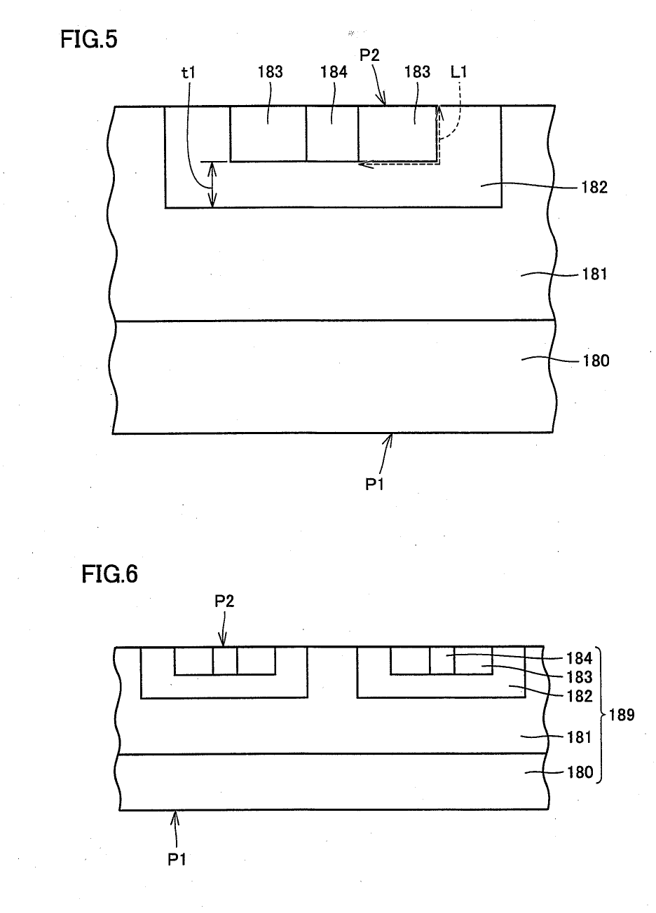

Referring to FIG. 6, epitaxial substrate 189 is formed by means of epitaxial growth on single-crystal substrate 180. As drift region 181, a portion of the epitaxial layer formed by the epitaxial growth can be used without any modification. This epitaxial growth can be performed by means of a CVD (Chemical Vapor Deposition) method. In doing so, hydrogen gas can be used as a carrier gas. As a source material gas, a mixed gas of silane (SiH₄) and propane (C₃H₈) can be employed, for example. In doing so, it is preferable to introduce nitrogen (N) or phosphorus (P) as an impurity, for example. Next, ions are implanted into the epitaxial layer so as to form body region 182, source region 183, and contact region 184.

Surface treatment may be provided to upper surface P2 of the epitaxial substrate by means of thermal etching. This etching can be performed by, for example, heating epitaxial substrate 189 in an atmosphere containing at least one or more types of halogen atom. The at least one or more types of halogen atom include at least one of chlorine (Cl) atom and fluorine (F) atom. This atmosphere is, for example, Cl₂, BCL₃, SF₆, or CF₄. With this thermal etching, a predetermined crystal plane (also referred to as “special plane”) is spontaneously formed in upper surface P2. The special plane will be described later.

Next, an activation annealing process is performed to activate the impurities introduced by the ion implantation. For example, heating is performed for 30 minutes at a temperature of approximately 1700° C. in an atmosphere of argon (Ar) gas. It should be noted that the above-described thermal etching may be performed after the activation annealing. In this case, atomic arrangement in the special plane can be prevented from being disarranged by the activation annealing.

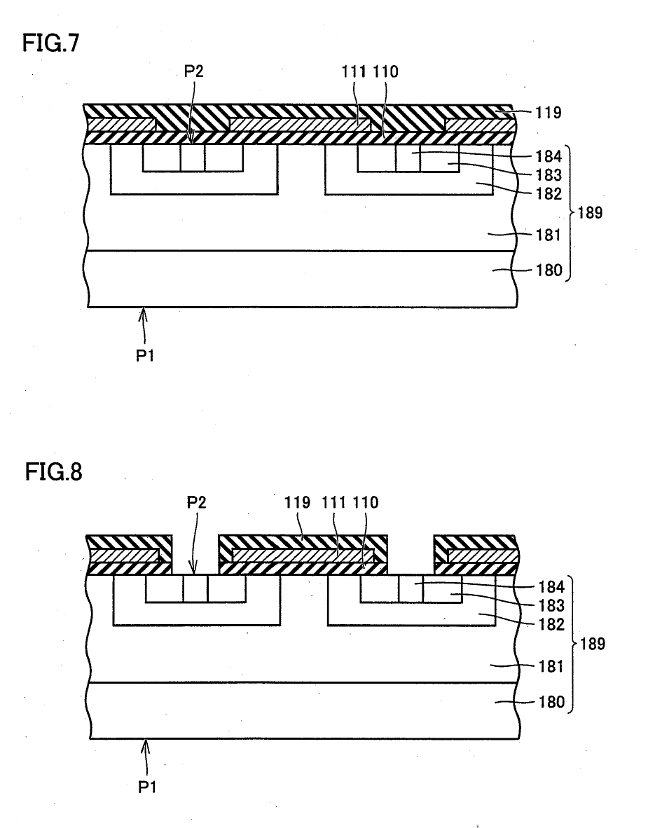

Referring to FIG. 7, gate oxide film 110 is formed on upper surface P2. Gate oxide film 110 is formed by means of, for example, thermal oxidation. The thermal oxidation is performed by performing heating for approximately 30 minutes at a temperature of approximately 1200° C. in air or oxygen, for example. Next, nitrogen annealing is performed. Accordingly, the nitrogen concentration is adjusted to have a maximum value of approximately 1×10²¹/cm³ or more in a region within 10 nm from an interface between epitaxial substrate 189 and gate oxide film 110. For example, in an atmosphere of gas containing nitrogen, such as nitrogen monoxide (NO) gas, heating is performed at a temperature of approximately 1100° C. for approximately 120 minutes. After this nitrogen annealing treatment, inert gas annealing treatment may be performed additionally. For example, in argon gas atmosphere, heating is performed at a temperature of approximately 1100° C. for approximately 60 minutes. Accordingly, high channel mobility can be attained with good reproducibility.

Next, gate electrode 111 is formed on gate oxide film 110. Next, interlayer insulating film 119 is formed to cover gate electrode 111 on gate oxide film 110.

As shown in FIG. 8, gate oxide film 110 and interlayer insulating film 119 are then patterned, thereby providing openings in each of which source region 183 and contact region 184 are exposed. This patterning can be performed by means of, for example, photolithography and etching.

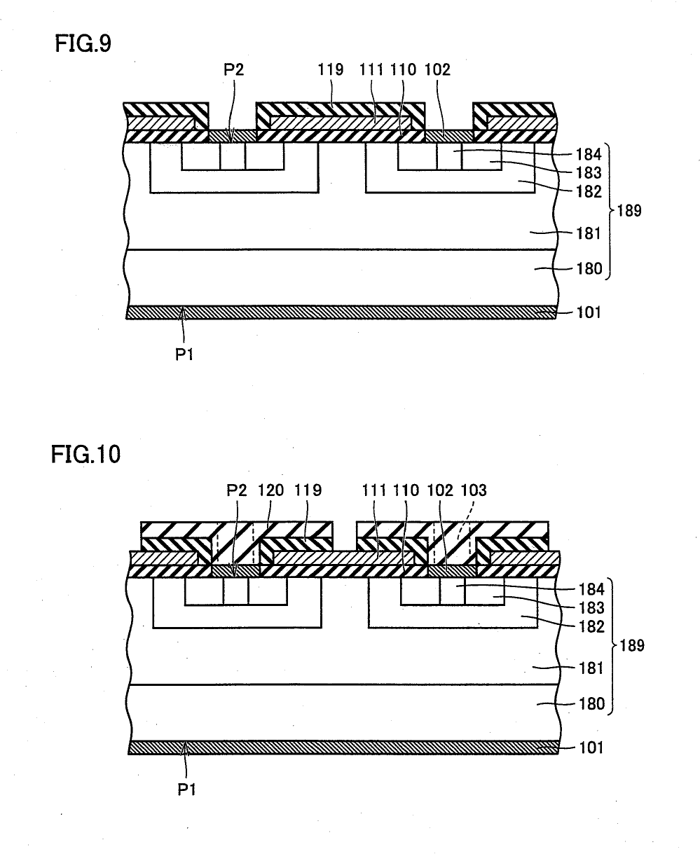

As shown in FIG. 9, in the opening, source electrode 102 is formed in contact with each of source region 183 and contact region 184. Further, drain electrode 101 is formed on lower surface P1 of epitaxial substrate 189.

Referring to FIG. 10, first, interlayer insulating film 120 is formed to cover each of interlayer insulating film 119 and source electrode 102. Next, a contact hole is formed to extend to gate electrode 111 through interlayer insulating films 120 and 119, and a contact hole is formed to extend to source electrode 102 through interlayer insulating film 120.

Referring to FIG. 1 again, source contact 103, source wire 104, gate contact 112, and gate wire 113 are formed. In this way, MOSFET 100 is obtained.

The following describes function and effect in the present embodiment.

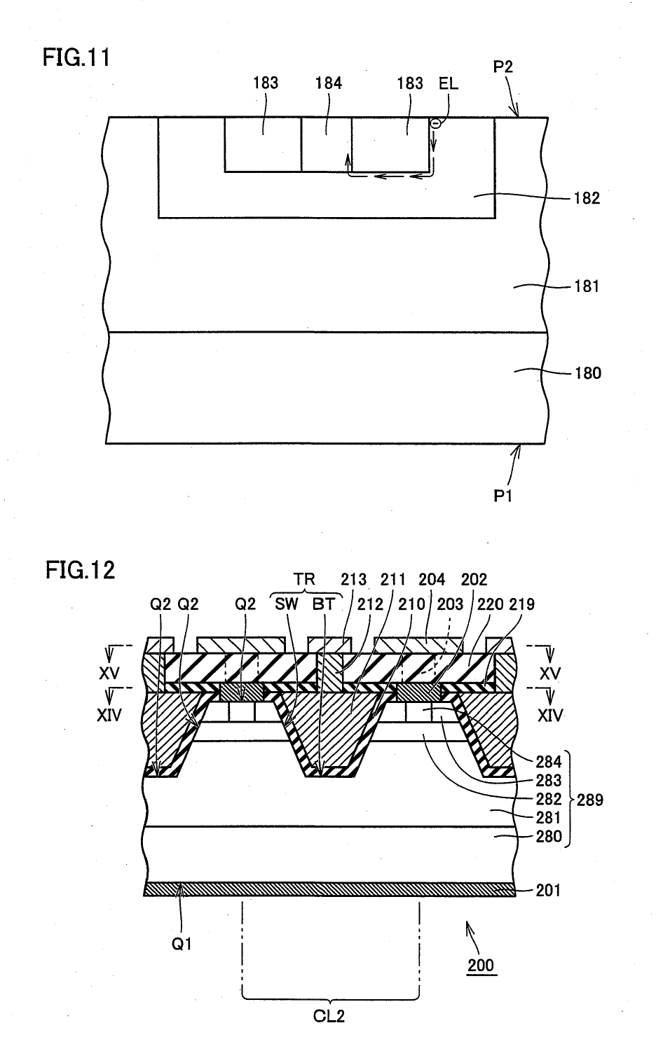

Referring to FIG. 11, when switching from ON state to OFF state, an inversion layer formed in the channel region of body region 182 ceases to exist. Specifically, electrons EL in the channel region are removed to source electrode 102 (not shown in FIG. 11) via contact region 184. If the migration of electrons EL in the channel region to contact region 184 is insufficient upon switching to OFF state, the insufficient removal of carriers in the channel region may result in fluctuations such that the threshold value for switching comes closer to zero as compared with an intended value, in an extreme case, such that the sign thereof is inversed.

According to MOSFET 100 of the present embodiment, contact region 184 is provided to surround body region 182 having the portion serving as the channel region (FIG. 2). Accordingly, when switching MOSFET 100 to OFF state, the carriers in the channel region can be removed in all the directions. This suppresses the carriers from remaining in the channel region during OFF state. Accordingly, fluctuations in threshold value for switching can be suppressed.

Preferably, distance L1 (FIG. 5) is approximately 3.5 μm or less from the portion, which is composed of body region 182, of upper surface P2 to contact region 184 via the interface between body region 182 and source region 183. This reduces a distance in which the carriers are migrated to be removed from the channel region to contact region 184 when switching to OFF state. Accordingly, when switching to OFF state, the carriers in the channel region can be sufficiently removed more securely.

Preferably, body region 182 has an impurity concentration of approximately 5×10¹⁷/cm³ or more. This reduces electric resistance in a path, which is disposed in body region 182 and in which the carriers are migrated to be removed from the channel region to contact region 184 when switching to OFF state. Accordingly, when switching to OFF state, the carriers in the channel region can be sufficiently removed more securely.

Preferably, body region 182 between drift region 181 and source region 183 has a thickness t1 (FIG. 5) of not less than approximately 0.2 μm and not more than approximately 1.5 μm. This reduces electric resistance in a path, which is disposed in body region 182 between drift region 181 and source region 183 and in which the carriers are migrated to be removed from the channel region to contact region 184 when switching to OFF state. Accordingly, when switching to OFF state, the carriers in the channel region can be sufficiently removed more securely.

### Second Embodiment

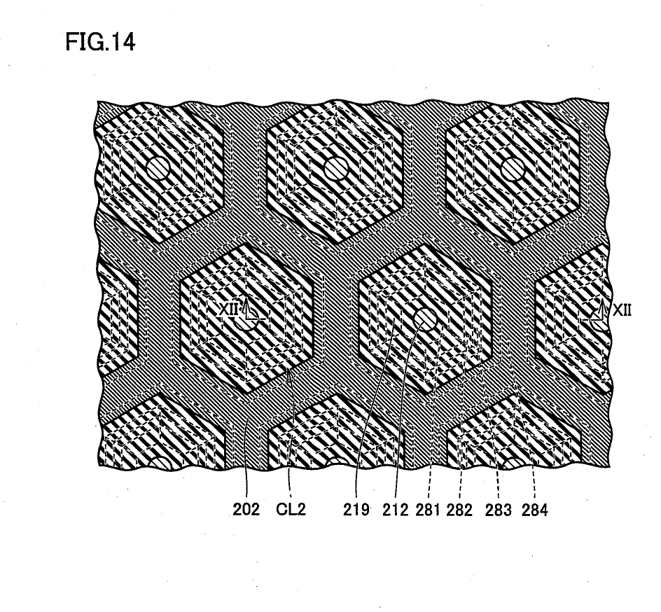

As shown in FIG. 12 to FIG. 15, a MOSFET 200 (silicon carbide semiconductor device) of the present embodiment is a trench type power semiconductor device, and has a plurality of cell structures CL2 periodically arranged. Specifically, MOSFET 200 includes an epitaxial substrate 289, a drain electrode 201 (first main electrode), source electrodes 202 (second main electrodes), source contacts 203, source wires 204, gate oxide films 210 (gate insulating films), gate electrodes 211, gate contacts 212, gate wires 213, and interlayer insulating films 219 and 220.

Epitaxial substrate 289 is made of silicon carbide. The silicon carbide preferably has a crystal structure of hexagonal system, more preferably, of polytype 4H. Epitaxial substrate 289 has a lower surface Q1 (first surface) and an upper surface Q2 (second surface). In upper surface Q2, a trench TR having side wall surfaces SW and a bottom surface BT is provided. Epitaxial substrate 289 includes: a single-crystal substrate 280; a drift region 281 (first region) having n type conductivity (first conductivity type); body regions 282 (second regions) having p type conductivity (second conductivity type different from the first conductivity type); source regions 283 (third regions) having n type conductivity; and contact regions 284 (fourth regions) having p type conductivity.

One surface of single-crystal substrate 280 constitutes lower surface Q1. Drift region 281 is provided on an opposite surface of single-crystal substrate 280 to this one surface. Drift region 281 constitutes a portion of bottom surface BT in upper surface Q2.

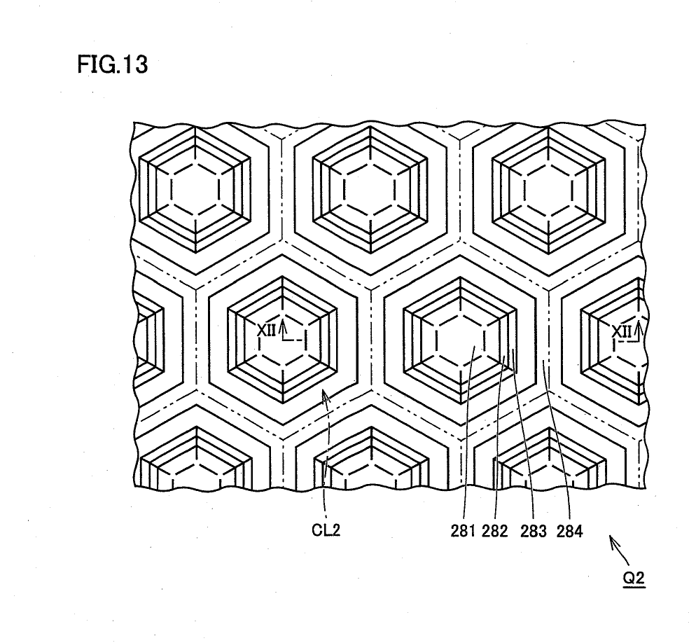

Each of body regions 282 is in contact with drift region 281. Body region 282 is separated from lower surface Q1 by drift region 281 (FIG. 12). On upper surface Q2, body region 282 surrounds drift region 281 (FIG. 13). Body region 282 preferably has an impurity concentration of not less than approximately 5×10¹⁷/cm³ and not more than approximately 3×10¹⁸/cm³, for example, has an impurity concentration of approximately 1×10¹⁸/cm³.

Preferably, body region 282 is an epitaxial layer provided on drift region 281. In other words, body region 282 is epitaxially grown on the drift region, and a conductive impurity in body region 282 has been introduced substantially during the epitaxial growth, and has not been introduced by means of ion implantation.

Source region 283 is in contact with body region 282. Source region 283 partially constitutes upper surface Q2. At upper surface Q2, source region 283 surrounds body region 282 (FIG. 13).

Contact region 284 is in contact with body region 282. Contact region 284 partially constitutes upper surface Q2. On upper surface Q2, contact region 284 surrounds source region 283 (FIG. 13). In the present embodiment, contact region 284 extends on upper surface Q2 in the form of a web so as to form a honeycomb shape. Contact region 284 has an impurity concentration higher than that of body region 282.

In upper surface Q2 of epitaxial substrate 289, trench TR is provided. Trench TR has side wall surfaces SW and bottom surface BT. Each of side wall surfaces SW extends to drift region 281 through source region 283 and body region 282. Thus, body region 282 constitutes a portion of side wall surface SW of upper surface Q2. Side wall surface SW has a channel surface of MOSFET 200 on body region 282. Trench TR is expanded toward the opening in a tapered manner. Side wall surface SW preferably has a plane orientation inclined by not less than approximately 50° and not more than approximately 65° relative to a {000-1} plane, more preferably, has a plane orientation inclined by not less than approximately 50° and not more than approximately 65° relative to a (000-1) plane. Preferably, side wall surface SW has a portion disposed particularly on body region 282 and having a predetermined crystal plane (also referred to as “special plane”). Details of the special plane will be described later. Bottom surface BT is disposed in drift region 281.

Drain electrode 201 is provided on lower surface Q1. Source electrode 202 is in contact with each of source region 283 and contact region 284. Gate oxide film 210 is provided on body region 282. Specifically, gate oxide film 210 covers body region 282 on side wall surface SW of trench TR. Gate electrode 211 is provided on gate oxide film 210.

Gate oxide film 210 covers side wall surface SW and bottom surface BT of trench TR. Hence, gate oxide film 210 covers body region 282 on side wall surface SW, which is a portion of upper surface Q2. Gate electrode 211 is provided on gate oxide film 210. Interlayer insulating film 219 covers gate electrode 211. Each of gate oxide film 210 and interlayer insulating film 219 has an opening in which each of source region 283 and contact region 284 is exposed on upper surface Q2. In this opening, source electrode 202 is in ohmic contact with each of source region 283 and contact region 284.

Gate contact 212 is provided in a contact hole, which is formed in each of interlayer insulating films 219 and 220, so as to connect gate wire 213 and gate electrode 211 to each other. Source wire 204 is provided on interlayer insulating film 220. Source contact 203 is provided in a contact hole, which is formed in interlayer insulating film 220, so as to connect source wire 204 and source electrode 202 to each other. Gate wire 213 is provided on interlayer insulating film 220. As shown in FIG. 15, gate wire 213 and source wire 204 are arranged alternately, and extend in the same direction.

Drain electrode 201 (FIG. 12) is provided on lower surface Q1 of epitaxial substrate 289. Drain electrode 201 is in ohmic contact with lower surface Q1 of the epitaxial substrate.

As shown in FIG. 16, a distance L2 is preferably approximately 3.5 μm or less from a portion, which is composed of body region 282, of upper surface Q2, i.e., a portion, which is composed of the body region, of side wall surface SW of trench TR, to contact region 284 via an interface between body region 282 and source region 283. Further, body region 282 between drift region 281 and source region 283 preferably has a thickness t2 (size in the longitudinal direction in the figure) of approximately 0.2 μm or more, more preferably, approximately 0.3 μm or more. Further, thickness t2 is preferably approximately 1.5 μm or less.

The following describes a method for manufacturing MOSFET 200.

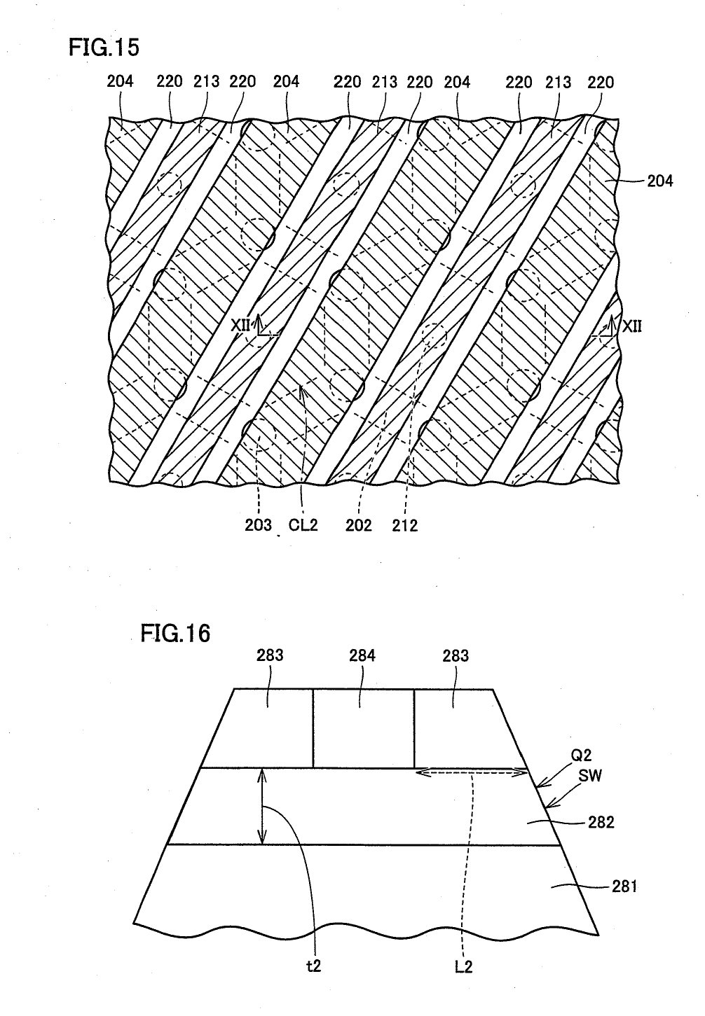

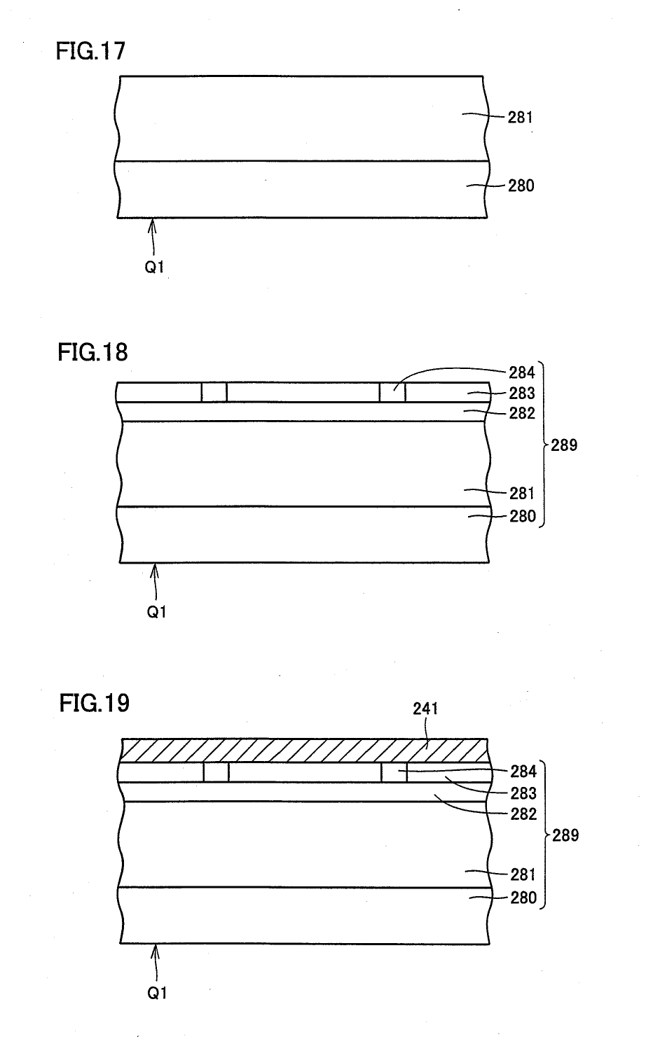

Referring to FIG. 17, a single-crystal substrate 280 having lower surface Q1 is prepared. Single-crystal substrate 280 has a surface (upper surface in the figure) that is opposite to lower surface Q1 and that preferably has an off angle of approximately 8° or less relative to a {000-1} plane, more preferably, an off angle of approximately 8° or less relative to a (000-1) plane. Further, this off angle is preferably more than approximately 2°. Next, drift region 281 is formed by means of epitaxial growth on the surface opposite to lower surface Q1. This epitaxial growth can be performed by means of the CVD method. In doing so, hydrogen gas can be used as a carrier gas. As a source material gas, a mixed gas of silane (SiH₄) and propane (C₃H₈) can be employed, for example. In doing so, it is preferable to introduce nitrogen (N) or phosphorus (P) as an impurity, for example.

Referring to FIG. 18, body region 282, source region 283, and contact region 284 are formed on drift region 281. Preferably, body region 282 is formed by means of epitaxial growth. In other words, a conductive impurity in body region 282 is introduced substantially during epitaxial growth. Such epitaxial growth can be performed by, for example, adding aluminum (Al) during growth of silicon carbide using the CVD method. Each of source region 283 and contact region 284 can be formed by means of ion implantation. It should be noted that body region 282 can be also formed by means of ion implantation rather than epitaxial growth.

Referring to FIG. 19, a protective film 241 is formed to cover source region 283 and contact region 284. Protective film 241 is, for example, a carbon film. Next, an activation annealing process is performed to activate the impurities introduced by the ion implantation. For example, heating is performed for 30 minutes at a temperature of approximately 1700° C. in an atmosphere of argon (Ar) gas. Next, protective film 241 is removed by means of etching.

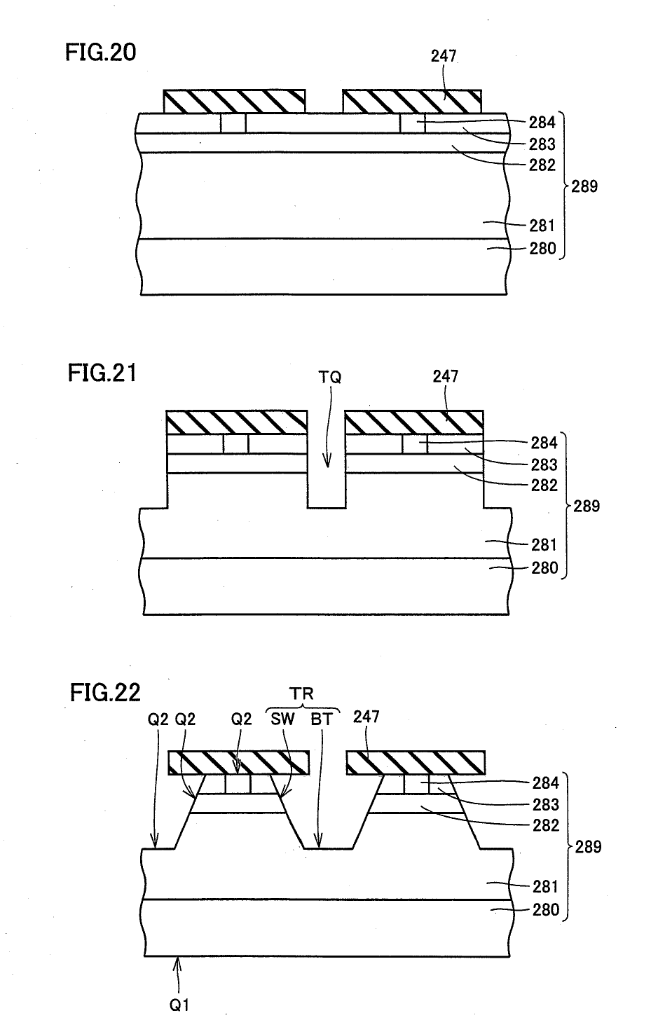

As shown in FIG. 20, a mask layer 247 having an opening is formed by means of a photolithography method on the surface composed of source region 283 and contact region 284. As mask layer 247, a silicon oxide film or the like can be used, for example. The opening is formed in conformity with the location of trench TR (FIG. 12). Next, trench TR (FIG. 12) is formed in epitaxial substrate 289 using mask layer 247. The following describes details thereof.

As shown in FIG. 21, in the opening of mask layer 247, source region 283, body layer 282, and a portion of drift region 281 are removed by etching. An exemplary, usable etching method is reactive ion etching (RIE), in particular, inductively coupled plasma (ICP) RIE. Specifically, for example, as a reactive gas, ICP-RIE can be employed which uses SF₆ or a mixed gas of SF₆ and O₂. By means of such etching, in the region where trench TR (FIG. 12) is to be formed, a recess TQ is formed which has a side wall substantially along the thickness direction (longitudinal direction in the figure) of epitaxial substrate 289.

Next, thermal etching is performed in recess TQ. The thermal etching can be performed by, for example, heating in an atmosphere containing reactive gas having at least one or more types of halogen atom. The at least one or more types of halogen atom include at least one of chlorine (Cl) atom and fluorine (F) atom. This atmosphere is, for example, Cl₂, BCL₃, SF₆, or CF₄. For example, the thermal etching is performed using a mixed gas of chlorine gas and oxygen gas as a reactive gas, at a heat treatment temperature of, for example, not less than approximately 700° C. and not more than approximately 1000° C.

It should be noted that the reactive gas may contain a carrier gas in addition to the chlorine gas and the oxygen gas. An exemplary, usable carrier gas is nitrogen (N₂) gas, argon gas, helium gas, or the like. When the heat treatment temperature is set at not less than approximately 700° C. and not more than approximately 1000° C. as described above, a rate of etching SiC is approximately, for example, 70 μm/hour. In addition, in this case, mask layer 247, which is formed of silicon oxide and therefore has a very large selection ratio relative to SiC, is not substantially etched during the etching of SiC.

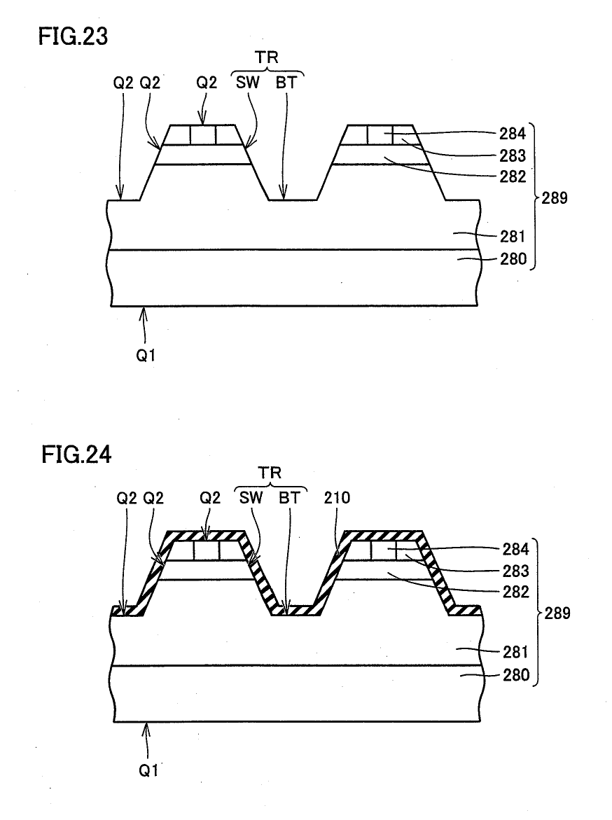

As a result of the above-described thermal etching, trench TR is formed in epitaxial substrate 289 as shown in FIG. 22. Preferably, during formation of trench TR, the special plane is spontaneously formed at side wall surface SW, in particular, at body region 282. Next, mask layer 247 is removed by means of an appropriate method such as etching (FIG. 23).

As shown in FIG. 24, gate oxide film 210 is formed to cover each of side wall surface SW and bottom surface BT of trench TR. Gate oxide film 210 can be formed by means of, for example, thermal oxidation.

After the formation of gate oxide film 210, NO annealing may be performed using nitrogen monoxide (NO) gas as an atmospheric gas. A temperature profile has, for example, the following conditions: a temperature of not less than approximately 1100° C. and not more than approximately 1300° C.; and a holding time of approximately 1 hour. In this way, nitrogen atoms are introduced into an interface region between gate oxide film 210 and body region 282. As a result, formation of interface state is suppressed in the interface region, thereby achieving improved channel mobility. It should be noted that a gas other than the NO gas may be employed as the atmospheric gas as long as such nitrogen atoms can be introduced.

After the NO annealing, Ar annealing may be additionally performed using argon (Ar) as an atmospheric gas. In the Ar annealing, the heating temperature is preferably higher than the heating temperature in the above-described NO annealing and lower than the melting point of gate oxide film 210. This heating temperature is held for, for example, approximately 1 hour. Accordingly, formation of interface state in the interface region between gate oxide film 210 and body region 282 can be further suppressed. It should be noted that a different inert gas such as nitrogen gas may be used as the atmospheric gas instead of the Ar gas.

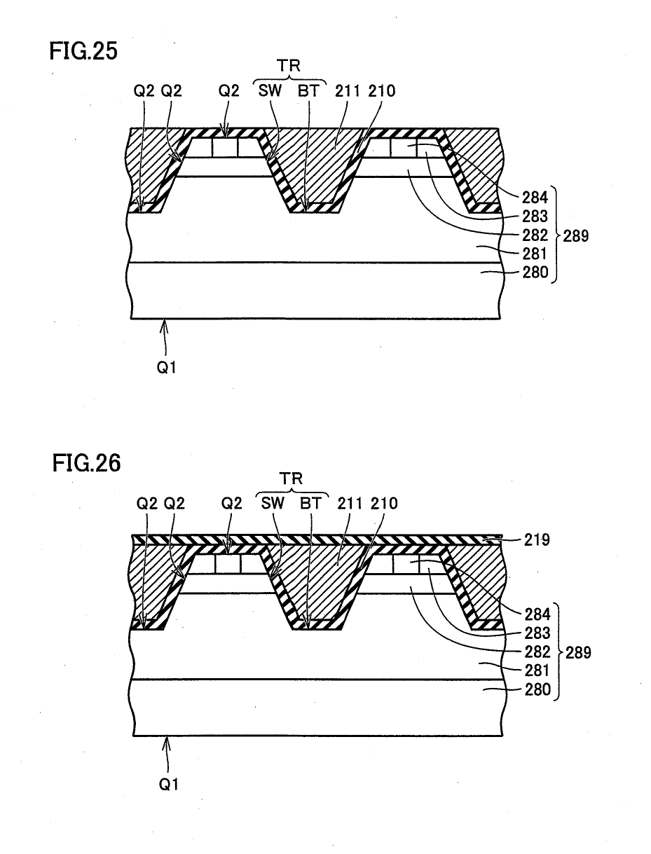

As shown in FIG. 25, gate electrode 211 is formed on gate oxide film 210. Specifically, gate electrode 211 is formed on gate oxide film 210 so as to fill the region inside trench TR with gate oxide film 210 being interposed therebetween. A method for forming gate electrode 211 can be performed by, for example, forming a film of conductor or doped polysilicon and performing CMP (Chemical Mechanical Polishing).

As shown in FIG. 26, interlayer insulating film 219 is formed to cover gate oxide film 210 and gate electrode 211.

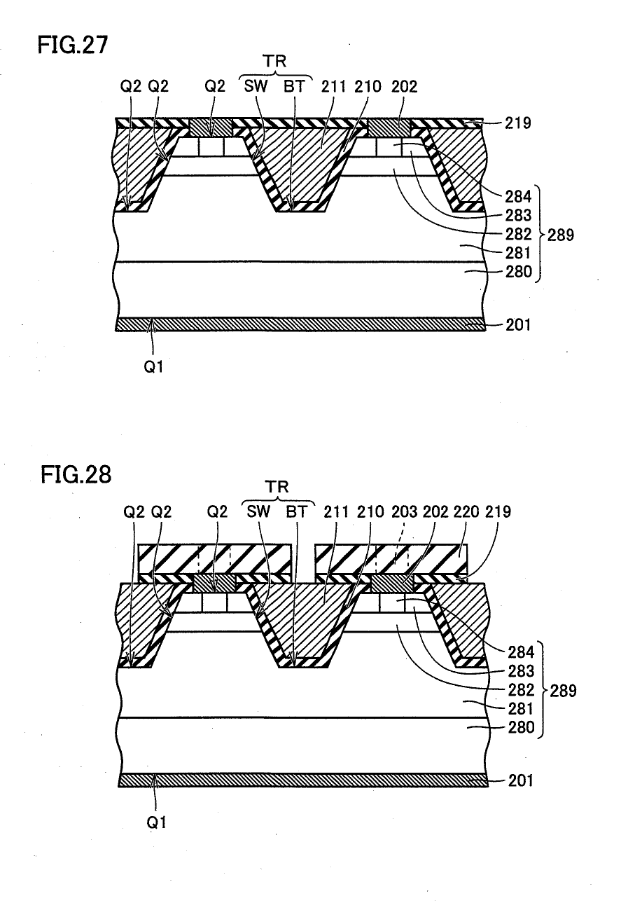

Referring to FIG. 27, etching is performed to form an opening in interlayer insulating film 219 and gate oxide film 210. Through the opening, each of source region 283 and contact region 284 is exposed on upper surface Q2. Next, on upper surface Q2, source electrode 202 is formed in contact with each of source region 283 and contact region 284. Further, drain electrode 201 is formed on lower surface Q1 of epitaxial substrate 289.

Referring to FIG. 28, first, interlayer insulating film 220 is formed to cover each of interlayer insulating film 219 and source electrode 202. Next, a contact hole is formed to extend to gate electrode 211 through interlayer insulating films 220 and 219, and a contact hole is formed to extend to source electrode 202 through interlayer insulating film 220.

Referring to FIG. 12 again, source contact 203, source wire 204, gate contact 212, and gate wire 213 are formed. In this way, MOSFET 200 is obtained.

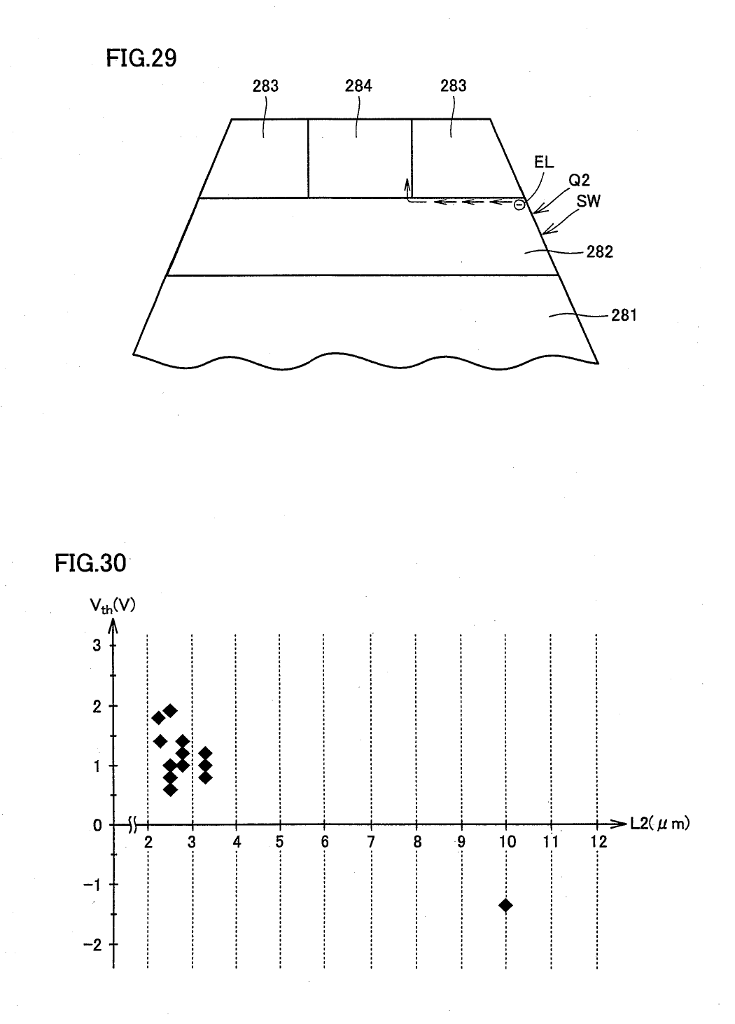

Referring to FIG. 29, when switching from ON state to OFF state, an inversion layer formed in the channel region of body region 282 ceases to exist. Specifically, electrons EL in the channel region are removed to source electrode 202 (not shown in FIG. 29) via contact region 284. If the migration of electrons EL in the channel region to contact region 284 is insufficient upon switching to OFF state, the insufficient removal of carriers in the channel region may result in fluctuations such that the threshold value for switching comes closer to zero as compared with an intended value, in an extreme case, such that the sign thereof is inversed. Also in the present embodiment, as with the first embodiment, fluctuations in threshold value can be suppressed.

Further, in the present embodiment, contact region 284 is provided to surround body region 282 having the portion serving as the channel region (FIG. 13). In such a plan layout, body region 284 needs to be contained in contact region 284. Accordingly, it is difficult to secure an area of body region 282 when viewed in a plan view (FIG. 13). Even though it is difficult to secure the area, on-resistance can be sufficiently reduced as long as the MOSFET is of trench type as in the present embodiment.

Preferably, distance L2 (FIG. 16) is approximately 3.5 μm or less. With this, as shown in FIG. 30, threshold voltage Vₜₕ can be avoided from being inversed.

Preferably, body region 282 is an epitaxial layer provided on drift region 281. Accordingly, crystal defect in body region 282 can be suppressed as compared with a case where body region 282 is a layer formed by ion implantation. This reduces electric resistance in a path, which is disposed in body region 282 and in which the carriers are migrated to be removed from the channel region to contact region 284 when switching to OFF state. Accordingly, when switching to OFF state, the carriers in the channel region can be sufficiently removed more securely.

It should be noted that in the first and second embodiments, each of cell structures CL1 and CL2 has a shape of substantially right hexagon, but the cell structure may have a different shape such as a rectangular shape or a square shape.

(As to Special Plane)

Upper surface P2 of epitaxial substrate 189 in the first embodiment (FIG. 1) preferably has a special plane particularly at its portion disposed on body region 182 and serving as the channel surface. Likewise, side wall surface SW of trench TR in the second embodiment (FIG. 12) preferably has a special plane particularly at its portion disposed on body region 282 and serving as the channel surface. The following fully describes the special plane while dealing with the case of the second embodiment.

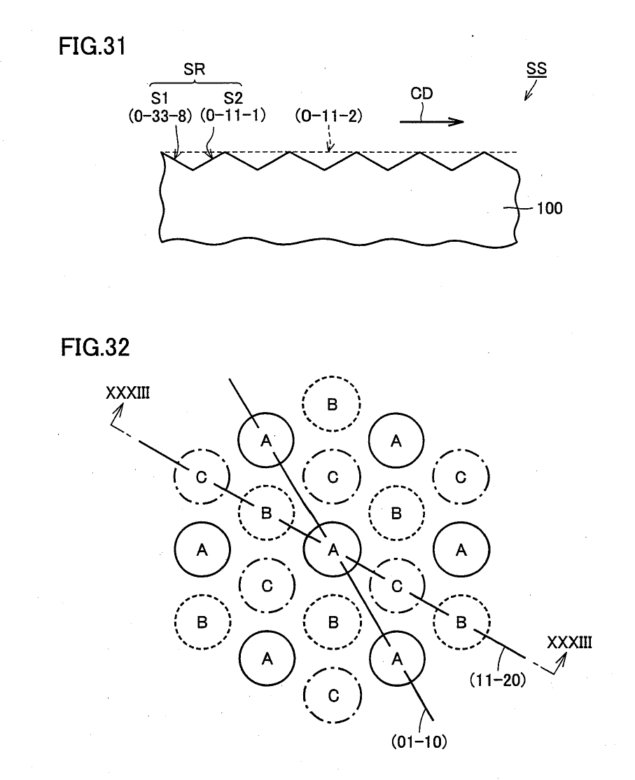

Referring to FIG. 31, a special plane SS includes a plane S1. Plane S1 has a plane orientation of {0-33-8}, and preferably has a plane orientation of (0-33-8). Preferably, special plane SS microscopically includes plane S1. Preferably, special plane SS further includes a plane S2, microscopically. Plane S2 has a plane orientation of {0-11-1}, and preferably has a plane orientation of (0-11-1). Here, the term “microscopically” refers to “minutely to such an extent that at least the size about twice as large as an interatomic spacing is considered”. As a method for observing such a microscopic structure, for example, a TEM (Transmission Electron Microscope) can be used.

Preferably, special plane SS has a combined plane SR. Combined plane SR is constituted of periodically repeated planes S1 and S2. Such a periodic structure can be observed by, for example, TEM or AFM (Atomic Force Microscopy). Combined plane SR has a plane orientation of {0-11-2}, and preferably has a plane orientation of (0-11-2). In this case, combined plane SR has an off angle of 62° relative to the {000-1} plane, macroscopically. Here, the term “macroscopically” refers to “disregarding a fine structure having a size of approximately interatomic spacing”. For the measurement of such a macroscopic off angle, a method employing general X-ray diffraction can be used, for example. Preferably, in the channel surface, carriers flow in a channel direction CD, in which the above-described periodic repetition is done.

The following describes a detailed structure of combined plane SR.

Generally, regarding Si atoms (or C atoms), when viewing a silicon carbide single-crystal of polytype 4H from the (000-1) plane, atoms in a layer A (solid line in the figure), atoms in a layer B (broken line in the figure) disposed therebelow, and atoms in a layer C (chain line in the figure) disposed therebelow, and atoms in a layer B (not shown in the figure) disposed therebelow are repeatedly provided as shown in FIG. 32. In other words, with four layers ABCB being regarded as one period, a periodic stacking structure such as ABCBABCBABCB . . . is provided.

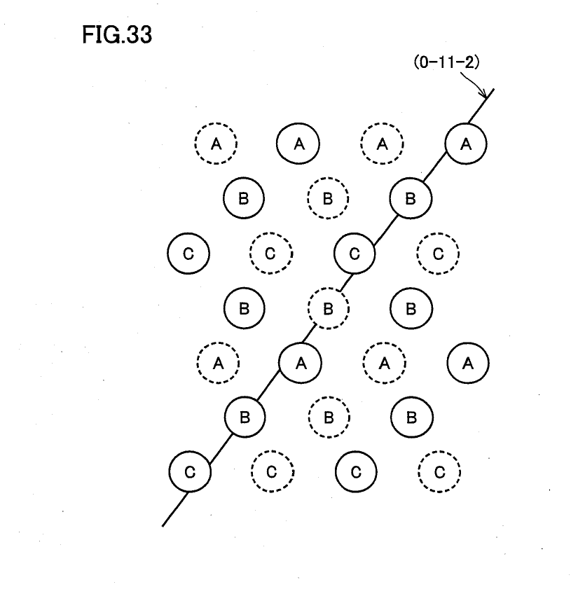

As shown in FIG. 33, in the (11-20) plane (cross section taken along a line XXXIII-XXXIII of FIG. 32), atoms in each of four layers ABCB constituting the above-described one period are not aligned completely along the (0-11-2) plane. In FIG. 33, the (0-11-2) plane is illustrated to pass through the locations of the atoms in layers B. In this case, it is understood that each of atoms in layers A and C is deviated from the (0-11-2) plane. Hence, even when the macroscopic plane orientation of the surface of the silicon carbide single-crystal, i.e., the plane orientation thereof with its atomic level structure being ignored is limited to (0-11-2), this surface can have various structures microscopically.

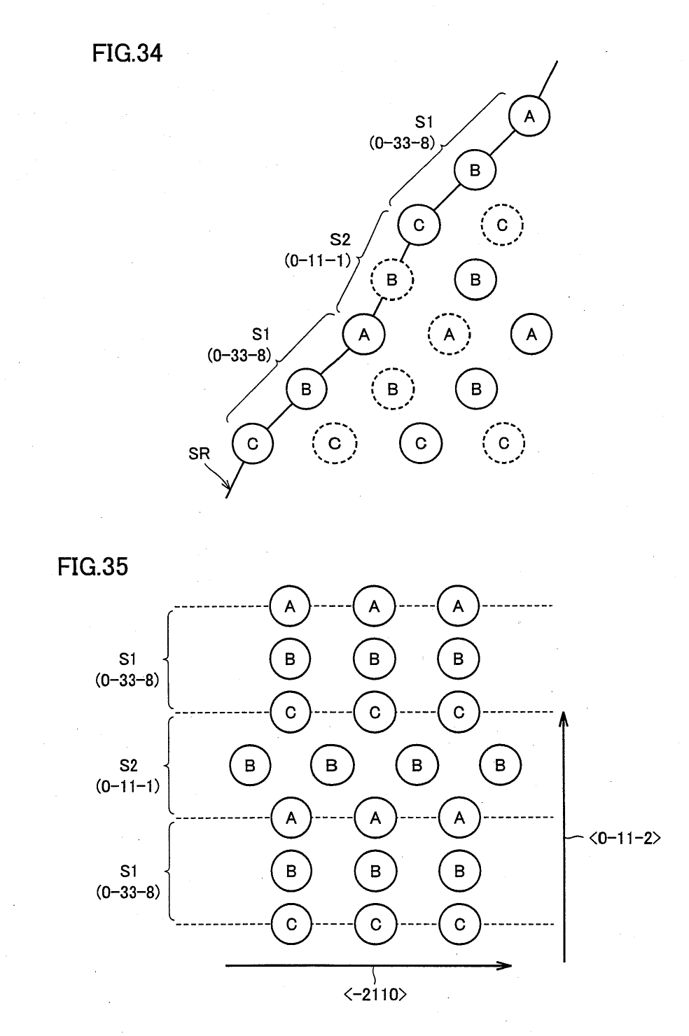

As shown in FIG. 34, combined plane SR is constructed by alternately providing planes S1 having a plane orientation of (0-33-8) and planes S2 connected to planes S1 and having a plane orientation different from that of each of planes S1. Each of planes S1 and S2 has a length twice as large as the interatomic spacing of the S1 atoms (or C atoms). It should be noted that a plane with plane S1 and plane S2 being averaged corresponds to the (0-11-2) plane (FIG. 33).

As shown in FIG. 35, when viewing combined plane SR from the (01-10) plane, the single-crystal structure has a portion periodically including a structure (plane S1 portion) equivalent to a cubic structure. Specifically, combined plane SR is constructed by alternately providing planes S1 having a plane orientation of (001) in the above-described structure equivalent to the cubic structure and planes S2 connected to planes S1 and having a plane orientation different from that of each of planes S1. Also in a polytype other than 4H, the surface can be thus constituted of the planes (planes S1 in FIG. 35) having a plane orientation of (001) in the structure equivalent to the cubic structure and the planes (planes S2 in FIG. 35) connected to the foregoing planes and having a plane orientation different from that of each of the foregoing planes. The polytype may be 6H or 15R, for example.

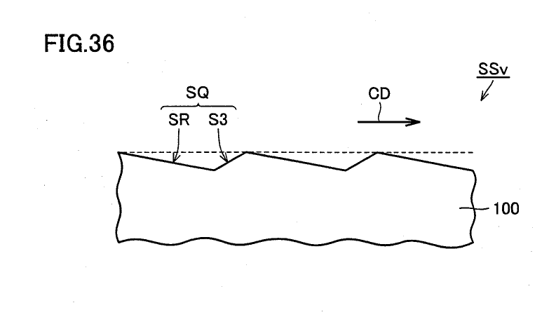

Referring to FIG. 36, a special plane SSv includes a plane S3 (third plane) in addition to combined plane SR (indicated by a straight line in a simplified manner in FIG. 36). The off angle of special plane SSv relative to the {000-1} plane is deviated from the ideal off angle of combined plane SR, i.e., 62°. Preferably, this deviation is small, preferably, in a range of ±10°. Examples of a surface included in such an angle range include a surface having a macroscopic plane orientation of the {0-33-8} plane. More preferably, the off angle of special plane SSv relative to the (000-1) plane is deviated from the ideal off angle of combined plane SR, i.e., 62°. Preferably, this deviation is small, preferably, in a range of +10°. Examples of a surface included in such an angle range include a surface having a macroscopic plane orientation of the (0-33-8) plane.

More specifically, special plane SSv may include a combined plane SQ constituted of periodically repeated plane S3 and combined plane SR. Such a periodic structure can be observed by, for example, TEM or AFM (Atomic Force Microscopy).

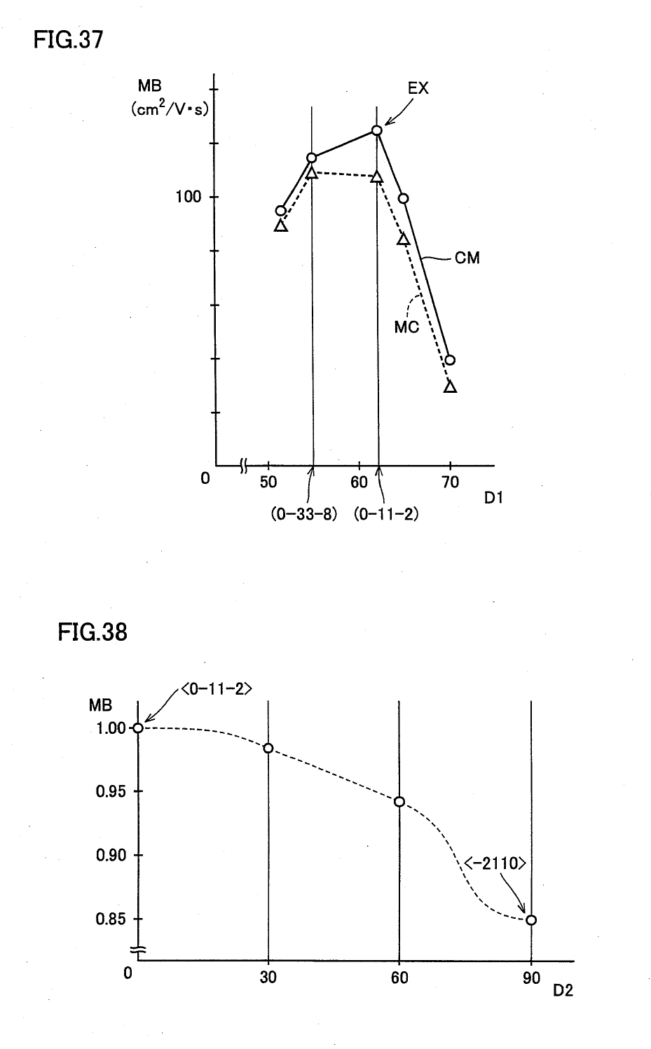

In the graph shown in FIG. 37, the horizontal axis represents an angle D1 formed by the (000-1) plane and the macroscopic plane orientation of the special plane, whereas the vertical axis represents mobility MB on a channel surface having such a special plane. A group of plots CM correspond to a case where the special plane is obtained with thermal etching being performed, whereas a group of plots MC correspond to a case where such thermal etching is not performed.

In group of plots MC, mobility MB is at maximum when the channel surface has a macroscopic plane orientation of (0-33-8). This is presumably due to the following reason. That is, in the case where the thermal etching is not performed, i.e., in the case where the microscopic structure of the channel surface is not particularly controlled, the macroscopic plane orientation thereof corresponds to (0-33-8), with the result that a ratio of the microscopic plane orientation of (0-33-8), i.e., the plane orientation of (0-33-8) in consideration of that in atomic level becomes statistically high.

On the other hand, mobility MB in group of plots CM is at maximum when the macroscopic plane orientation of the channel surface is (0-11-2) (arrow EX). This is presumably due to the following reason. That is, as shown in FIG. 34 and FIG. 35, the multiplicity of planes S1 each having a plane orientation of (0-33-8) are densely and regularly arranged with planes S2 interposed therebetween, whereby a ratio of the microscopic plane orientation of (0-33-8) becomes high in the channel surface.

It should be noted that mobility MB has orientation dependency on combined plane SR. In a graph shown in FIG. 38, the horizontal axis represents an angle D2 between the channel direction and the <0-11-2> direction, whereas the vertical axis represents mobility MB (in any unit) in the channel surface. A broken line is supplementarily provided therein for viewability of the graph. From this graph, it has been found that in order to increase channel mobility MB, channel direction CD (FIG. 31) preferably has an angle D2 of approximately not less than 0° and not more than 60°, more preferably, substantially 0°.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A silicon carbide semiconductor device comprising a silicon carbide substrate having a first surface and a second surface,
said silicon carbide substrate including
a first region that has first conductivity type,
a second region that has second conductivity type different from said first conductivity type, that is in contact with said first region, that is separated from said first surface by said first region, that partially constitutes said second surface, and that surrounds said first region on said second surface,
a third region that has said first conductivity type, that is in contact with said second region, that partially constitutes said second surface, and that surrounds said second region on said second surface, and
a fourth region that has said second conductivity type, that has an impurity concentration higher than that of said second region, that is in contact with said second region, that partially constitutes said second surface, and that surrounds said third region on said second surface,
said silicon carbide semiconductor device further comprising:
a first main electrode provided on said first surface;
a second main electrode in contact with each of said third region and said fourth region;
a gate insulating film provided on said second region; and
a gate electrode provided on said gate insulating film.

2. The silicon carbide semiconductor device according to claim 1, wherein a distance is 3.5 μm or less from a portion, which is composed of said second region, of said second surface to said fourth region via an interface between said second region and said third region.

3. The silicon carbide semiconductor device according to claim 1, wherein said second region has an impurity concentration of 5×10¹⁷/cm³ or more.

4. The silicon carbide semiconductor device according to claim 1, wherein said second region is an epitaxial layer provided on said first region.

5. The silicon carbide semiconductor device according to claim 1, wherein said second region between said first region and said third region has a thickness of not less than 0.2 μm and not more than 1.5 μm.

6. The silicon carbide semiconductor device according to claim 1, wherein a trench having a side wall is provided in said second surface of said silicon carbide substrate, and said second region is covered with said gate insulating film on said side wall.

7. The silicon carbide semiconductor device according to claim 1, wherein said second surface of said silicon carbide substrate is flat.
